(19) United States
(12) Patent Application Publication
(10) Pub. No.: US 2024/0181593 A1
(43) Pub. Date: Jun. 6, 2024

(54) POLISHING PROCESS APPARATUS

(71) Applicant: SAMSUNG ELECTRONICS CO., LTD., Suwon-si (KR)

(72) Inventors: Wonkeun CHO, Suwon-si (KR); Eungchul KIM, Suwon-si (KR); Taesung KIM, Suwon-si (KR); Donghoon KWON, Suwon-si (KR); Hyunmo AN, Suwon-si (KR); Suengjun OH, Suwon-si (KR)

(73) Assignee: SAMSUNG ELECTRONICS CO., LTD., Suwon-si (KR)

(21) Appl. No.: 18/228,481

(22) Filed: Jul. 31, 2023

(30) Foreign Application Priority Data
Dec. 1, 2022 (KR) 10-2022-0165689

(51) Int. Cl. B24B 37/013

(52) U.S. Cl. CPC B24B 37/013

(57) ABSTRACT

A polishing process apparatus includes a carrier configured to support an object, a platen provided below the carrier and configured to accommodate at least one eddy current sensor, the at least one eddy current sensor including a coil configured to output an eddy current, a power supply circuit configured to supply power to the coil and a voltage detection circuit connected to the coil and configured to detect raw voltage data, a polishing pad on an upper surface of the platen, and a controller configured to acquire first data by receiving the raw voltage data from the voltage detection circuit a plurality of times while a polishing process is performed on the object, acquire second data by sequentially applying a first filter and a second filter to the first data, the first filter being different from the second filter and measure a thickness of a target layer included in the object based on the second data.

### CROSS-REFERENCE TO RELATED APPLICATION(S)

This application claims priority to Korean Patent Application No. 10-2022-0165689, filed on Dec. 1, 2022 in the Korean Intellectual Property Office, the disclosure of which is incorporated by reference herein in its entirety.

### BACKGROUND

### 1. Field

Example embodiments of the disclosure relate to a polishing process apparatus.

### 2. DESCRIPTION OF RELATED ART

In a semiconductor process, a polishing process during may refer to a process of fully or partially removing a target layer to form a desired thickness. In order to accurately determine an end point of the polishing process, a thickness of the target layer needs to be accurately detected. The related art may include various methods for detecting the thickness of the target layer removed by the polishing process. However, since a minimum thickness measurable from the target layer is fixed, the end point of the polishing process cannot be accurately determined in the related art methods.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a polishing process apparatus capable of precisely controlling a thickness of a target layer by accurately determining an end point of a polishing process by detecting the thickness of the target layer in real time, while the polishing process is in progress.

Additional aspects will be set forth in part in the description which follows and, in part, will be apparent from the description, or may be learned by practice of the presented embodiments.

According to an aspect of an example embodiment, a polishing process apparatus may include a carrier configured to support an object, a platen provided below the carrier and configured to accommodate at least one eddy current sensor, the at least one eddy current sensor including a coil configured to output an eddy current, a power supply circuit configured to supply power to the coil and a voltage detection circuit connected to the coil and configured to detect raw voltage data, a polishing pad on an upper surface of the platen, and a controller configured to acquire first data by receiving the raw voltage data from the voltage detection circuit a plurality of times while a polishing process is performed on the object, acquire second data by sequentially applying a first filter and a second filter to the first data, the first filter being different from the second filter and measure a thickness of a target layer included in the object based on the second data.

According to an aspect of an example embodiment, a polishing process apparatus may include a carrier configured to support an object, a platen provided below the carrier and including a plurality of spaces configured to accommodate a plurality of eddy current sensors, where each of the plurality of eddy current sensors may include a coil, a power supply circuit configured to supply alternating current (AC) power to the coil and a voltage detection circuit configured to detect raw voltage data corresponding to impedance of the coil, and a polishing pad on an upper surface of the platen and configured to polish a target layer in the object, where the voltage detection circuit may include an input resistor configured to receive a coil voltage corresponding to an inductance of the coil, a feedback resistor connected to the input resistor, an operational amplifier including a first input terminal connected to a node between the input resistor and the feedback resistor and a second input terminal connected to a reference node, and a resistance regulator configured to regulate a resistance value of the feedback resistor.

According to an aspect of an example embodiment, a polishing process apparatus may include a platen configured to provide a space in which at least one eddy current sensor is accommodated, where the at least one eddy current sensor may include a coil, a power supply circuit configured to supply AC power to the coil, an amplification circuit configured to output an analog voltage signal corresponding to a change in impedance of the coil and an ADC configured to convert the analog voltage signal into raw voltage data, a polishing pad on an upper surface of the platen, and a controller configured to acquire raw voltage data from the at least one eddy current sensor, determine an end point of a polishing process, and increase a gain of the amplification circuit over time after the polishing process starts.

### BRIEF DESCRIPTION OF DRAWINGS

The above and other aspects, features, and advantages of certain example embodiments of the present disclosure will be more apparent from the following description taken in conjunction with the accompanying drawings, in which:

FIGS. 1 and 2 diagrams illustrating a polishing process apparatus according to an embodiment of the disclosure;

FIG. 3 is a diagram illustrating an eddy current sensor included in a polishing process apparatus according to an embodiment of the disclosure;

FIG. 4 is a diagram illustrating a polishing process apparatus according to an embodiment of the disclosure;

FIG. 5 is a flowchart illustrating an operation of a polishing process apparatus according to an embodiment of the disclosure;

FIG. 6 is a graph illustrating an operation of an eddy current sensor during a polishing process in a polishing process apparatus according to an embodiment of the disclosure;

FIGS. 7, 8, 9 and 10 are diagrams illustrating a polishing process performed in a polishing process apparatus according to an embodiment of the disclosure;

FIG. 11 is a diagram illustrating an eddy current sensor included in a polishing process apparatus according to an embodiment of the disclosure;

FIGS. 12 and 13 are graphs illustrating an operation of a polishing process apparatus according to an embodiment of the disclosure;

FIG. 14 is a diagram illustrating an operation of a polishing process apparatus according to an embodiment of the disclosure;

FIGS. 15, 16 and 17 are diagrams illustrating a polishing process apparatus according to an embodiment of the disclosure; and

FIG. 18 is a diagram illustrating an operation of a polishing process apparatus according to an embodiment of the disclosure.

### DETAILED DESCRIPTION

Hereinafter, embodiments of the present inventive concept will be described with reference to the accompanying drawings.

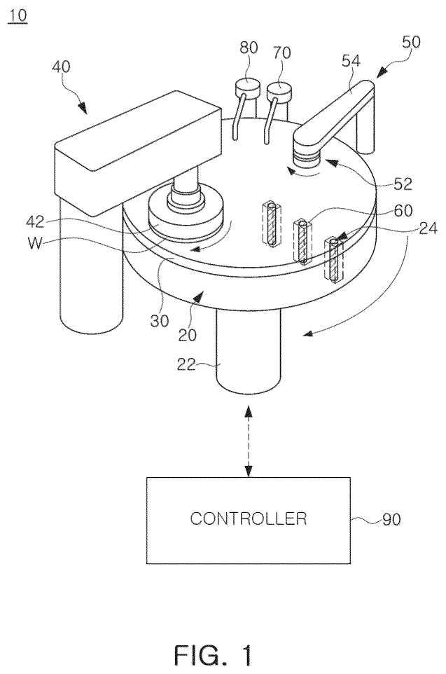

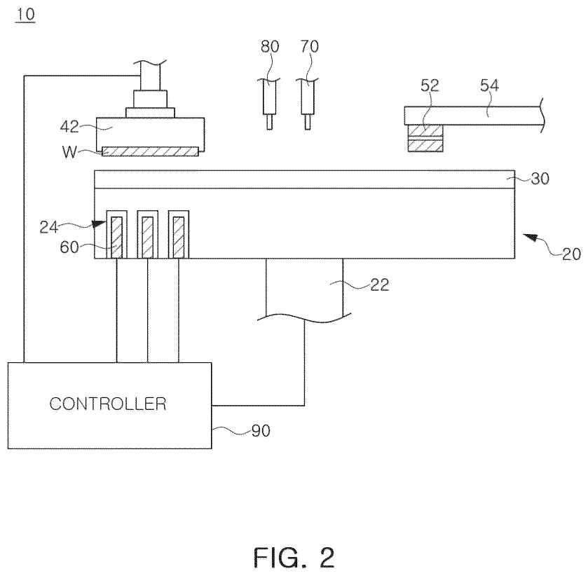

FIGS. 1 and 2 diagrams illustrating a polishing process apparatus according to an embodiment of the disclosure.

Referring to FIGS. 1 and 2, a polishing process apparatus 10 according to an embodiment of the disclosure may include a platen 20 having an upper surface to which a polishing pad 30 is attached, a carrier 40 supporting an object to be polished, such as a wafer W or the like, a pad conditioner 50 conditioning a polishing surface that is an upper surface of the polishing pad 30, and nozzles 70 and 80 supplying a material to the polishing pad 30 while a polishing process is performed.

For example, the nozzles 70 and 80 may include a first nozzle 70 supplying a slurry solution to an upper surface of the polishing pad 30 and a second nozzle 80 supplying fluid to the upper surface of the polishing pad 30. The slurry solution sprayed from the first nozzle 70 may include chemicals and abrasives, and in an embodiment, the slurry solution may include fine abrasive particles, such as colloidal silica. A target layer of a wafer W may be chemically planarized by the slurry solution sprayed onto the upper surface of the polishing pad 30.

The second nozzle 80 may supply a fluid for temperature control to the upper surface of the polishing pad 30. For example, the second nozzle 80 may supply a gas mixed with deionized water to the upper surface of the polishing pad 30, and the gas may include nitrogen, oxygen, carbon dioxide, and the like.

A plurality of semiconductor dies may be disposed in a lattice form on the wafer W, which is an object to be polished, and each of the plurality of semiconductor dies may include one or more layers. For example, the uppermost layer among one or more layers may be a target layer of a polishing process, and the wafer W may be mounted on the carrier 40 such that the target layer protrudes out of a polishing head 42.

The polishing head 42 may press the target layer against the polishing pad 30. The polishing head 42 may be fixed to the driving shaft of the carrier 40 and rotate. The polishing head 42 may include a retaining ring, and the wafer W may be secured under a flexible membrane inside the polishing head 42.

The platen 20 may have a rotatable disk shape on which the polishing pad 30 is seated. The platen 20 may be rotated by a driving shaft 22. In the embodiment illustrated in FIG. 1, the platen 20 and the polishing head 42 are rotated in the same direction, but are not necessarily limited thereto. The polishing pad 30 may include abrasive particles to polish and remove the target layer of the wafer W. For example, the polishing pad 30 may include an elastic material, such as polyurethane having a rough surface.

The pad conditioner 50 may regenerate surface roughness to a certain level by grinding the surface of the polishing pad 30 when the polishing pad 30 is worn. Pressure may be applied while the conditioner disk 52 of the pad conditioner 50 contacts the surface of the polishing pad 30. For example, when the polishing pad 30 is used for a predetermined period of time or longer, abrasive particles present in the polishing pad 30 may be damaged due to frictional contact with the target layer of the wafer W. By regenerating the polishing pad 30 using the pad conditioner 50, lifetime of the polishing pad 30 may be improved.

As illustrated in FIGS. 1 and 2, a plurality of spaces 24 may be formed inside the platen 20, and at least one eddy current sensor 60 may be disposed in each of the plurality of spaces 24. As is described in detailed below, the eddy current sensor 60 may include a power supply circuit outputting alternating current (AC) power, a coil generating eddy current upon receiving AC power from the power supply circuit, and a voltage detection circuit detecting a voltage from the coil.

A thickness of the target layer included in the wafer W gradually decreases through the polishing process, a magnitude of the voltage detected from the coil included in the eddy current sensor 60 may vary. The controller 90 may perform the polishing process by rotating the platen 20 and the polishing head 42, and, during the polishing process acquire raw voltage data corresponding to a voltage level of the coil included in the eddy current sensor 60 to measure a thickness of the target layer.

In an embodiment of the disclosure, the controller 90 may measure the thickness of the target layer, while changing a resolution of the eddy current sensor 60 as time elapses after the polishing process starts. For example, the controller 90 may maintain the resolution of the eddy current sensor 60 at an initial value until a predetermined reference time elapses from the start of the polishing process, and at this time, a minimum thickness of the target layer measurable by the eddy current sensor 60 may be a first thickness. When the polishing process starts and the reference time elapses, the controller 90 may increase the resolution of the eddy current sensor 60 to adjust the minimum thickness of the target layer measurable by the eddy current sensor 60 to a second thickness smaller than the first thickness.

For example, if the thickness of the target layer is measured without changing the resolution of the eddy current sensor 60 during the polishing process, the thickness of the target layer cannot be accurately measured after the thickness of the target layer is reduced to be smaller than the first (e.g., initial) thickness by the polishing process. In an embodiment of the disclosure, the thickness of the target layer may be more precisely measured by reducing the minimum measurable thickness of the target layer by changing the resolution of the eddy current sensor 60 according to the duration of the polishing process. Therefore, an end point of the polishing process may be accurately determined.

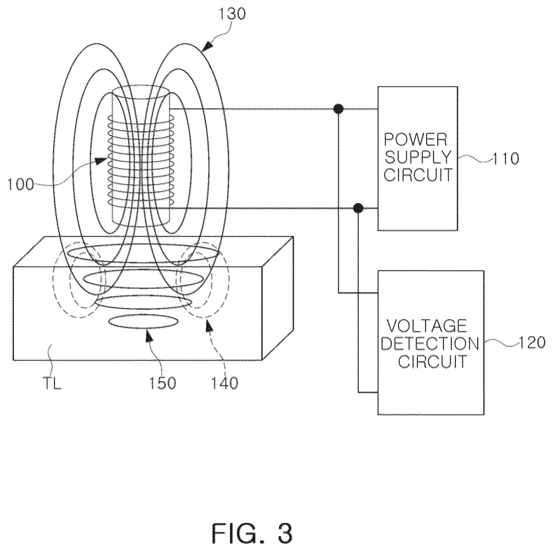

FIG. 3 is a diagram illustrating an eddy current sensor included in a polishing process apparatus according to an embodiment of the disclosure.

Referring to FIG. 3, an eddy current sensor according to an embodiment of the disclosure may include a coil 100, a power supply circuit 110 connected to the coil 100, and a voltage detection circuit 130. The power supply circuit 110 may apply AC power to the coil 100, and for example, a primary magnetic field 130 may be generated as illustrated in FIG. 3 by a current flowing through the coil 100.

When the target layer TL approaches the eddy current sensor in a state in which a current is applied to the coil 100 and the primary magnetic field 130 is generated, an induced electromotive force may be generated in the target layer TL by electromagnetic induction. The induced electromotive force may generate an eddy current 150 that disturbs the primary magnetic field 130 according to Lenz's Law.

A secondary magnetic field 140 interfering with the primary magnetic field 130 may be generated in the target layer TL by the eddy current 150. The eddy current 150 may change according to a material, thickness, etc., of the target layer TL, and accordingly, the secondary magnetic field 140 may change. The change in the secondary magnetic field 140 may lead to a change in the primary magnetic field 130, and the change in the primary magnetic field 130 may appear as a change in impedance of the coil 100.

The voltage detection circuit 120 may detect the change in impedance of the coil 100 in the form of an analog voltage signal, convert the analog voltage signal into digital raw voltage data, and output the converted raw voltage data. The controller receiving the raw voltage data from the voltage detection circuit 120 may determine a thickness of the target layer TL using the raw voltage data. Also, the controller may change the resolution of the eddy current sensor by changing a gain of the voltage detection circuit 120 or the like. For example, the controller may increase the gain of the voltage detection circuit 120 as time elapses after the polishing process starts to increase the resolution of the eddy current sensor and more accurately measure the thickness of the target layer TL.

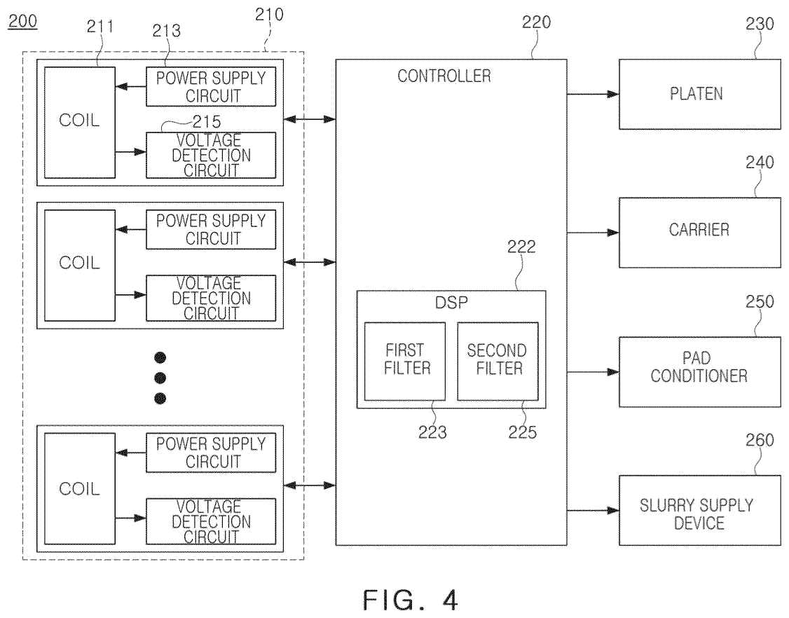

FIG. 4 is a diagram illustrating a polishing process apparatus according to an embodiment of the disclosure.

Referring to FIG. 4, a polishing process apparatus 200 according to an embodiment of the disclosure includes a plurality of eddy current sensors 210, a controller 220, a platen 230, a carrier 240, a pad conditioner 250, a slurry supply device 260, and the like. Operations of the platen 230, the carrier 240, the pad conditioner 250, and the slurry supply device 260 may be understood with reference to the embodiments described above with reference to FIGS. 1 and 2.

For example, the controller 220 may perform the polishing process of removing at least a portion of the target layer included in the object by rotating each of the carrier 240 and the platen 230 in a state in which the object is fixed to the carrier 240. As the polishing process is in progress, surface roughness of the polishing pad mounted on an upper surface of the platen 230 may be lowered, and the controller 220 may grind the surface of the polishing pad with the pad conditioner 250. In addition, the controller 220 may supply a slurry to the surface of the polishing pad using the slurry supply device 260, while the polishing process is performed.

As described above with reference to FIGS. 1 and 2, the plurality of eddy current sensors 210 may be installed in a plurality of spaces provided by the platen 230. Each of the plurality of eddy current sensors 210 may include a coil 211, a power supply circuit 213, and a voltage detection circuit 215, and the controller 220 may control the plurality of eddy current sensors 210.

When the polishing process starts, the controller 220 may control the power supply circuit 213 to supply AC power to the coil 211 in each of the plurality of eddy current sensors 210. When current flows through the coil 211 by the AC power, a primary magnetic field may be formed around the coil 211, and accordingly, an eddy current and a secondary magnetic field may be formed in the target layer of the object adjacent to the platen 230.

When the thickness of the target layer decreases as the polishing process is in progress, an intensity of the eddy current may change. The voltage detection circuit 215 may detect an analog voltage signal corresponding to a change in impedance of the coil 211 and output raw voltage data, which is a digital signal. For example, a level of the analog voltage signal may decrease as the thickness of the target layer decreases as the polishing process is in progress.

The controller 220 may monitor the thickness of the target layer in real time while the polishing process is in progress, using the raw voltage data received from the voltage detection circuit of each of the plurality of eddy current sensors 210. The controller 220 may include a digital signal processor (DSP) 222 filtering the raw voltage data (e.g., the controller 220 may acquire first data based on the raw voltage data). The DSP 222 may apply a first filter 223 and a second filter 225 to the raw voltage data to remove noise of the raw voltage data and improve accuracy of measuring the thickness of the target layer (e.g., the controller 220 may acquire second data by filtering the first data and/or by filtering the raw voltage data). For example, the first filter 223 may be a moving average filter, and the second filter 225 may be a one-dimensional Kalman filter.

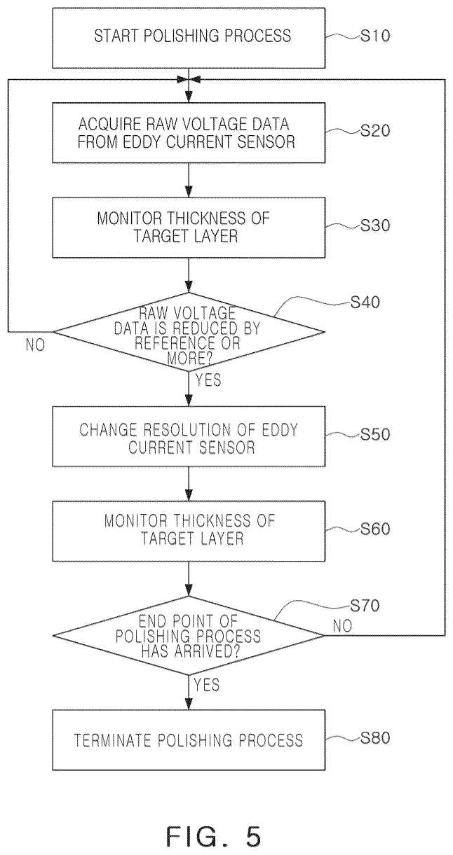

FIG. 5 is a flowchart illustrating an operation of a polishing process apparatus according to an embodiment of the disclosure.

Referring to FIG. 5, the polishing process apparatus according to an embodiment of the disclosure may start a polishing process in operation S10. Before starting the polishing process, an object to be polished may be fixed to a carrier of a polishing process apparatus, and at least a portion of a target layer included in the object may be removed by the polishing process. A controller of the polishing process apparatus may start the polishing process by pressing the object against the polishing pad, while rotating the platen on which the polishing pad is mounted and the carrier on which the object is fixed.

While the polishing process is performed, the controller of the polishing process apparatus may obtain raw voltage data from an eddy current sensor received in a space inside the platen in operation S20. The eddy current sensor may detect an analog voltage signal corresponding to a change in impedance of a coil generating eddy current in the target layer, convert the analog voltage signal into raw voltage data, and output the converted raw voltage data. The controller may monitor a thickness of the target layer in real time with reference to the raw voltage data in operation S30.

While monitoring the thickness of the target layer in real time, the controller may determine whether the raw voltage data is reduced by a reference value or more in operation S40. For example, as the thickness of the target layer decreases in the polishing process, the level of the analog voltage signal may gradually decrease, and thus, the raw voltage data corresponding to the analog voltage signal may also decrease over time after the polishing process starts. According to an embodiment, operation S40 may be replaced with or be performed in conjunction with an operation of determining whether a predetermined reference time has elapsed from the start of the polishing process. For example, the condition determination of operation S40 may be a determination as to whether a raw voltage data is reduced by a reference value or more and/or whether a predetermined reference time has elapsed from the start of the polishing process.

If it is determined in operation S40 that the raw voltage data has not decreased by the reference value or more (and/or that the predetermined reference time has elapsed from the start of the polishing process) (e.g., NO in operation S40), the controller may acquire the raw voltage data from the eddy current sensor and continue/repeat operations S20 and S30 of monitoring the thickness of the target layer based on the raw voltage data based on the acquired row voltage data. If it is determined that the raw voltage data is reduced by the reference value or more in operation S40 (e.g., YES in operation S40), the controller may change the resolution of the eddy current sensor in operation S50. For example, the controller may change the resolution of the eddy current sensor by adjusting a gain of an amplification circuit outputting a change in impedance of a coil as an analog voltage signal in the eddy current sensor. After changing the resolution of the eddy current sensor, the controller may monitor the thickness of the target layer again based on the raw voltage data in operation S60.

The controller may determine whether an end point of the polishing process arrives while the eddy current sensor outputs the raw voltage data with the changed resolution in operation S70. For example, in operation S70, the controller may determine whether the end point of the polishing process has arrived based on whether the thickness of the target layer monitored in operation S60 has reached a target thickness. The controller may determine whether the end point of the polishing process has arrived based on a thickness of the target layer and/or based on a duration time of the polishing process (e.g., whether a predetermined amount of time has elapsed may be used to determine whether the end point of the polishing process has arrived)

If it is determined in operation S70 that the end point of the polishing process has not yet arrived (e.g., NO in operation S70), the controller may repeat operations S20 to S60. In other words, according to an embodiment, the resolution of the eddy current sensor may be changed two or more times before the end point arrives after the polishing process starts.

If it is determined that the end point of the polishing process has arrived in operation S70 (e.g., YES in operation S70), the controller may terminate the polishing process in operation S80. When the polishing process is terminated, the object may be separated from the carrier and carried out of the polishing process apparatus by a wafer transfer robot or the like, and a new object to be polished may be carried into the polishing process apparatus for a next polishing process.

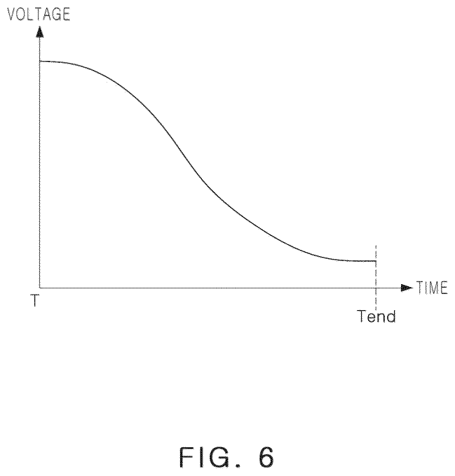

FIG. 6 is a graph illustrating an operation of an eddy current sensor during a polishing process in a polishing process apparatus according to an embodiment of the disclosure.

FIG. 6 is be a graph illustrating a change in voltage level of an analog voltage signal detected by an eddy current sensor from a coil while a polishing process is performed. As time elapses from a start time TO of the polishing process to an end time Tend of the polishing process, the voltage level of the analog voltage signal may gradually decrease. However, the decreasing trend of the analog voltage signal is not necessarily limited to that illustrated in FIG. 6.

As illustrated in FIG. 6, the analog voltage signal may decrease because the thickness of the target layer gradually decreases while the polishing process is in progress. A case in which the thickness of the target layer significantly decreases instantaneously rarely occurs stochastically, and thus, the analog voltage signal may have a tendency to gradually decrease over time.

In consideration of such a decreasing trend of the signal, the controller of the polishing process apparatus may remove the effect of noise by using a moving average filter for raw voltage data obtained by digitally converting the analog voltage signal. The moving average filter may be a filter that calculates an average of current data and a predetermined number of previous data. In addition, along with the moving average filter, a one-dimensional (1D) Kalman filter for estimating current data using data of an immediately previous time point may be used. In other words, the current data may be predicted based on previous data using the moving average filter, and the 1D Kalman filter may be applied to the predicted value of the current data and an actual value of the current data received from the eddy current sensor. Accordingly, an effect of lowering an average error, while minimizing a delay time due to filtering, may be obtained.

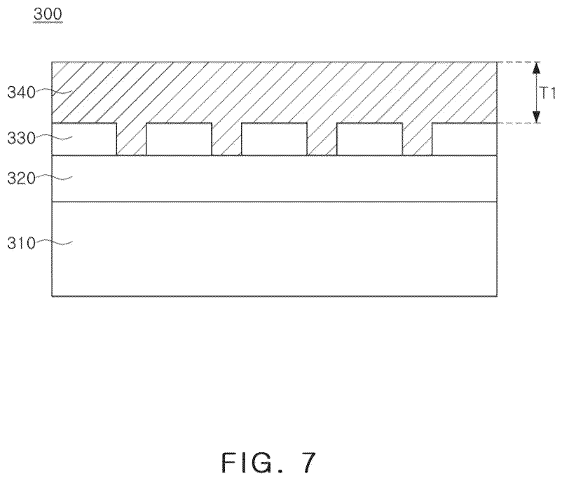

FIGS. 7, 8, 9 and 10 are diagrams illustrating a polishing process performed in a polishing process apparatus according to an embodiment of the disclosure.

Referring to FIGS. 7 to 10, an object to be polished 300 that is a target of a polishing process may include a semiconductor substrate 310 and a plurality of layers 320 to 340 stacked on the semiconductor substrate 310. A polishing process is performed on a target layer 340 formed at the top of the plurality of layers 320 to 340, and a thickness of the target layer 340 may be monitored in real time, while the polishing process is performed, by generating an eddy current in the target layer 340 by an eddy current sensor. For example, the target layer 340 may be formed of a conductive material.

FIG. 7 may be a view briefly illustrating the object 300 before the polishing process starts. Referring to FIG. 7, before the polishing process starts, the target layer 340 may have a first thickness T1. For example, the purpose of the polishing process described with reference to FIGS. 7 to 10 may be to expose patterns of a third layer 330 by removing the target layer 340 by the first thickness T1.

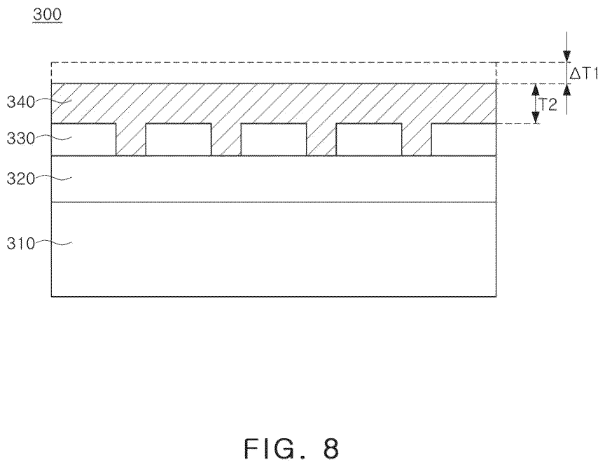

When the polishing process starts, the controller connected to the eddy current sensor of the polishing process apparatus may monitor the thickness of the target layer 340 by operating the eddy current sensor. For example, referring to FIG. 8, for a first period of time after the polishing process starts, the target layer 340 may be removed by a first thickness variation ΔT1. Accordingly, the thickness of the target layer 340 may decrease from the first thickness T1 to a second thickness T2.

A voltage level of an analog voltage signal generated by the eddy current sensor may decrease for the first period of time, and an intensity of raw voltage data obtained by converting the analog voltage signal into a digital signal may also decrease during the first period of time. For example, the raw voltage data may decrease below a first reference intensity after the lapse of the first period of time. When the raw voltage data decreases below the first reference intensity, the controller may monitor the thickness of the target layer 340 in more detail by increasing the resolution of the eddy current sensor.

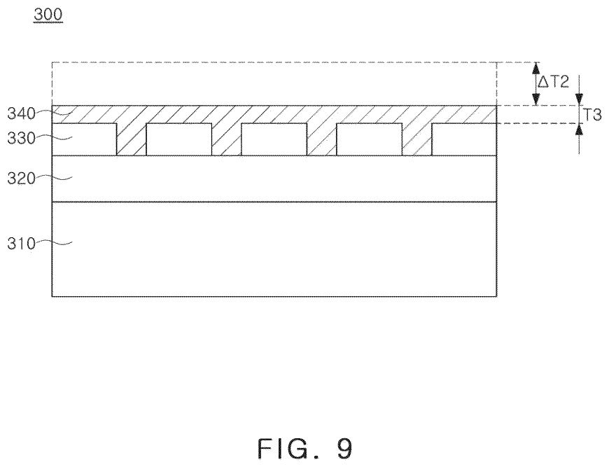

When a second period of time longer than the first period of time elapses after the polishing process starts, the thickness of the target layer 340 may decrease to a third thickness T3 as illustrated in FIG. 9. Referring to FIG. 9, the target layer 340 may be removed by a second thickness variation ΔT2 during the second period of time. The raw voltage data that the controller acquires from the eddy current sensor may decrease below a second reference intensity smaller than the first reference intensity, and the controller may further increase the resolution of the eddy current sensor.

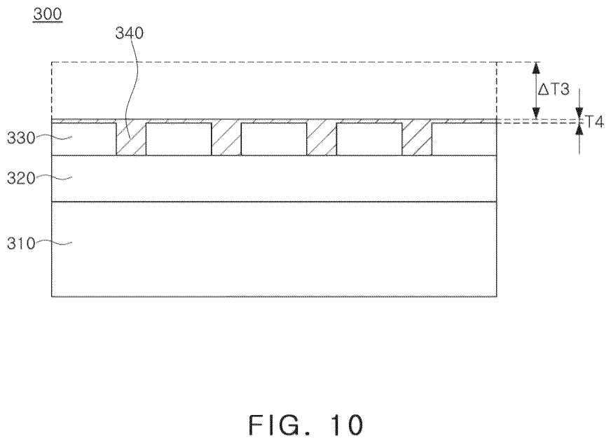

Referring to FIG. 10, as a third time elapses after the polishing process starts, the thickness of the target layer 340 may decrease to a fourth thickness T4. The third period of time may be longer than the second period of time, and the thickness of the target layer 340 may decrease by a third thickness variation ΔT3 by the polishing process during the third time period.

When the third period of time elapses after the polishing process starts, the thickness of the target layer 340 may decrease so that the raw voltage data may decrease below a third reference intensity as illustrated in FIG. 10. For example, the third reference intensity may be smaller than the first reference intensity and the second reference intensity. When the raw voltage data is detected to be below the third reference intensity, the controller may monitor the thickness of the target layer 340 in more detail by further increasing the resolution of the eddy current sensor.

The controller may determine whether the polishing process is terminated based on a result of monitoring the thickness of the target layer 340. For example, if an end point of the polishing process is determined to be too early, the polishing process may be terminated with the target layer 340 remaining on the patterns of the third layer 330, so that the patterns of the third layer 330 may not be exposed to the outside. If the end point of the polishing process is determined to be too late, the target layer 340 may be removed excessively and at least a partial region of the patterns of the third layer 330 may be removed by the polishing process.

In an embodiment of the disclosure, the controller may adjust the resolution of the eddy current sensor by referring to at least one of an elapsed time after the polishing process starts and an intensity of raw voltage data output from the eddy current sensor. As described above, the controller may monitor the remaining thickness of the target layer 340 in more detail by increasing the resolution of the eddy current sensor as the elapsed time increases or as the intensity of the raw voltage data decreases. Therefore, the controller may accurately determine the end point of the polishing process, and a defect rate of the polishing process may be reduced.

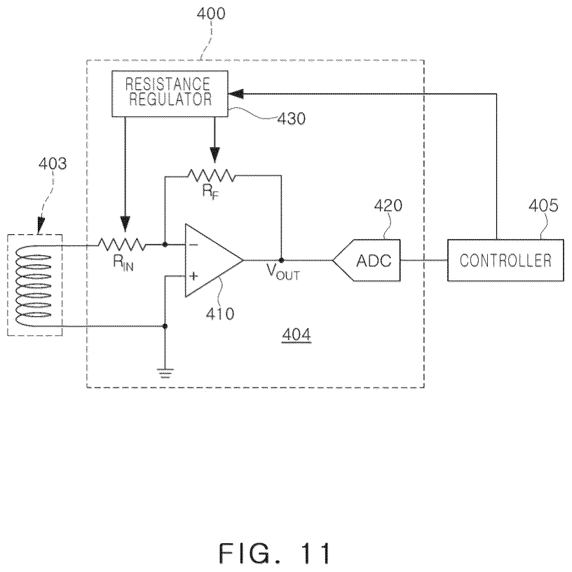

FIG. 11 is a diagram illustrating an eddy current sensor included in a polishing process apparatus according to an embodiment of the disclosure.

Referring to FIG. 11, an eddy current sensor 400 according to an embodiment of the disclosure may include a coil 403 and a voltage detection circuit 404. AC power may be supplied to the coil 403 so that current may flow, a magnetic field may be formed due to the current flowing through the coil 403, and the magnetic field may form an eddy current in a target layer of an object to be polished adjacent to the coil 403.

The voltage detection circuit 404 may include an operational amplifier 410, an analog-to-digital converter (ADC) 420, and a resistance regulator 430. The operational amplifier 410 may be connected to the coil 403 by a first resistor R_{IN}, and a coil voltage corresponding to impedance of the coil 403 may be input to the first resistor R_{IN}. The first resistor R_{IN} may be referred to as an input resistor. The first resistor R_{IN} may be connected to a first input terminal of the operational amplifier 410, and a second resistor RF may be connected between the first input terminal and an output terminal of the operational amplifier 410. The second resistor RF may be referred to as a feedback resistor. A reference voltage may be input to a second input terminal of the operational amplifier 410, and in the embodiment illustrated in FIG. 11, the reference voltage may be a ground voltage.

The operational amplifier 410, the first resistor R_{IN}, and the second resistor RF provide an amplification circuit, and the coil voltage may be amplified by a gain determined according to a ratio of the first resistor R_{IN} and a second resistor RF and input to the ADC 420 as an output voltage V_{OUT}. The ADC 420 may convert the output voltage V_{OUT} into raw voltage data that is a digital signal and transmit the converted raw voltage data to a controller 405.

In response to control data received from the controller 405, the resistance regulator 430 may change a resistance value of at least one of the first resistor R_{IN} and the second resistor RF. In other words, a ratio between a resistance value of the first resistor R_{IN} and a resistance value of the second resistor RF may be adjusted by the resistance regulator 430, and as a result, a gain of the amplification circuit may be changed.

For example, when a predetermined reference time or more has lapsed since the polishing process started, or when a thickness of the target layer determined based on the raw voltage data acquired from the eddy current sensor 400 is equal to or less than a predetermined reference thickness, the controller 405 may output control data for changing a resistance value of at least one of the first resistor R_{IN} and the second resistor RF to the resistance regulator 430. The resistance regulator 430 may decrease the resistance value of the first resistor R_{IN} or increase the resistance value of the second resistor RF in response to the control data.

As described above with reference to FIG. 6, the output voltage V_{OUT} of the amplification circuit may have a tendency of gradually decreasing over time after the polishing process starts. Therefore, if the gain of the amplification circuit is maintained even after the polishing process starts, the intensity of the raw voltage data may also decrease, and as a result, the resolution of the eddy current sensor 400 may decrease and the controller 405 may not accurately monitor the thickness of the target layer.

In an embodiment of the disclosure, by decreasing the resistance value of the first resistor R_{IN} or increasing the resistance value of the second resistor RF according to the passage of time and/or the decrease in the intensity of the raw voltage data, the gain of the amplification circuit may increase. Therefore, despite the decrease in the thickness of the target layer, the level of the output voltage V_{OUT} and the intensity of the raw voltage data may be maintained above a certain level, and as a result, an effect of increasing the resolution of the eddy current sensor 400 may be obtained. For example, the increase in resolution of the eddy current sensor 400 may correspond to a decrease in a minimum thickness measurable by the eddy current sensor 400. In an embodiment of the disclosure, by increasing the resolution of the eddy current sensor 400 as the time of the polishing process elapses, the change in thickness of the target layer may be more precisely measured, and as a result, the end time of the polishing process may be more accurately measured.

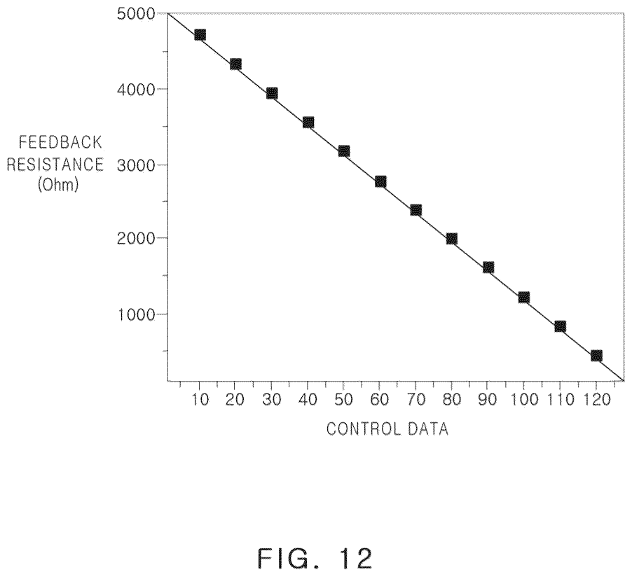

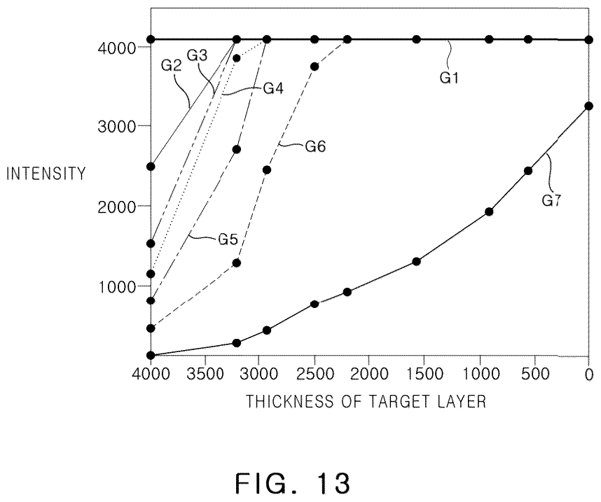

FIGS. 12 and 13 are graphs illustrating an operation of a polishing process apparatus according to an embodiment of the disclosure.

Hereinafter, for convenience of description, the operation of the polishing process apparatus will be described with reference to the eddy current sensor 400 illustrated in FIG. 11. FIG. 12 is be a graph illustrating feedback resistance according to a value of control data output from the controller 405 to the resistance regulator 430. The feedback resistance may be a resistance value of the second resistor RF connected between the first input terminal and the output terminal of the operational amplifier 410 in the eddy current sensor 400 illustrated in FIG. 11. FIG. 13 is be a graph illustrating the intensity of raw voltage data over the thickness of the target layer according to the gain of the amplification circuit.

Referring to the graph illustrated in FIG. 12, the feedback resistance may change linearly according to the value of control data. In the embodiment illustrated in FIG. 12, the control data may be 7-bit data, and thus, the control data may be changed in 128 steps. In the embodiment illustrated in FIG. 12, the feedback resistance tends to gradually decrease as the control data increases, but the disclosure is not necessarily limited thereto, and the feedback resistance may be designed to increase as the control data increases.

As illustrated in FIG. 12, if the eddy current sensor 400 is designed such that the feedback resistance decreases as the control data increases, the controller 405 may decrease the value of the control data as time elapses after the polishing process starts. Accordingly, as time elapses, the feedback resistance may increase, and accordingly, the gain of the eddy current sensor 400 may increase, such that a minimum thickness of the target layer that may be determined by the controller 405 may decrease.

Referring to FIG. 13, each of the first to seventh lines G1 to G7 may represent the intensity of raw voltage data received by the controller 405 according to the thickness of the target layer under a condition that the amplification circuit has different gains. For example, the first line G1 may correspond to a case in which the gain of the amplification circuit is the smallest first gain, and the seventh line G7 may correspond to a case in which the gain of the amplification circuit is the largest seventh gain. In other words, the first line G1 may correspond to a case in which the control data is the largest and the feedback resistance is the smallest, and the seventh line G7 may correspond to a case in which the control data is the smallest and the feedback resistance is the largest.

Referring to the first line G1, after the thickness of the target layer decreases to 4000 Å or less, the change in thickness of the target layer may not be reflected in the intensity of the raw voltage data. In other words, when the gain of the amplification circuit is the first gain and the thickness of the target layer is 4000 Å and the thickness of the target layer is 1000 Å, the eddy current sensor 400 may output raw voltage data having the same intensity to the controller 405.

Referring to the second line G2, when the target layer has a thickness of 3200 Å or more as the gain of the amplification circuit increases to the second gain, raw voltage data may be generated with a smaller intensity. Accordingly, the minimum thickness of the target layer that the controller 405 may determine based on the raw voltage data may be reduced to 3200 Å. In the case of the third line G3, in which the gain of the amplification circuit is a third gain greater than the second gain, the minimum thickness of the target layer that the controller 405 may determine may be 3200 Å, similar to the second line G2. However, compared to the second line G2, since the intensity of the raw voltage data changes more significantly according to the change in the thickness of the target layer, the thickness of the target layer may be more accurately measured in the third line G3.

Trends of the fourth line G4 and the fifth line G5 may be similar to those of the second line G2 and the third line G3. Referring to FIG. 13, in each case of the fourth line G4 and the fifth line G5, the minimum measurable thickness of the target layer may be about 3000 Å. However, as illustrated in FIG. 13, since the change in the intensity of the raw voltage data according to the change in the thickness of the target layer is larger in the fifth line G5 than in the fourth line G4, the controller 405 may measure the thickness of the target layer more precisely in the case in which the gain of the amplification circuit is the fifth gain than in the case in which the gain of the amplification circuit is the fourth gain.

The sixth line G6 corresponds to an embodiment in which the gain of the amplification circuit is set to the sixth gain, and in this case, the minimum thickness of the target layer that may be measured by the controller 405 may be reduced to about 2300 Å. As illustrated in the seventh line G7, when the gain of the amplification circuit increases to the seventh gain, the controller 405 may measure the thickness of the target layer in units of several Å.

In the embodiment described with reference to FIGS. 12 and 13, as time elapses after the polishing process starts, the gain of the amplification circuit may be increased from the first gain, which is an initial value, to the seventh gain by changing the control data output from the controller 405 to the resistance regulator 430. By increasing the gain of the amplification circuit up to the seventh gain, the thickness of the target layer may be precisely measured up to several Å, and as a result, the end point of the polishing process may be accurately determined. In other words, a difference between the thickness of the target layer remaining after the polishing process is finished and the preset target thickness may be minimized.

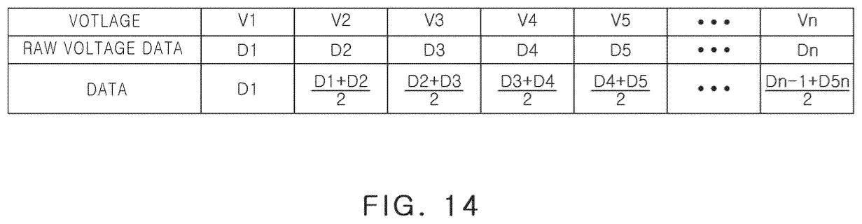

FIG. 14 is a diagram illustrating an operation of a polishing process apparatus according to an embodiment of the disclosure.

FIG. 14 is a table illustrating a moving average filter included in a controller in a polishing process apparatus according to an embodiment of the disclosure. In an embodiment of the disclosure, as the polishing process starts, the controller may sequentially receive raw voltage data D1 to Dn. The amplification circuit of the eddy current sensor may output analog voltage signals V1 to Vn at predetermined points in time, and the analog voltage signals V1 to Vn may be converted into digital raw voltage data D1 to Dn by an ADC and may be input to the controller.

As illustrated in FIG. 14, the controller may filter the raw voltage data D1 to Dn using an average of previous data which is received immediately before and current data, thereby generating data for measuring the thickness of the target layer. However, this is only an embodiment, and the controller may generate data for measuring the thickness of the target layer by an average of two or more pieces of previous data and current data.

As described above with reference to FIG. 6, the voltage level of the analog voltage signals V1 to Vn output by the eddy current sensor may decrease as the polishing process is in progress. Accordingly, when the raw voltage data received by the controller at a specific point in time is significantly reduced or increased compared to the raw voltage data received at a previous point in time, it may be considered that the influence of noise is significantly reflected in the raw voltage data. Considering the trend of the analog voltage signals V1 to Vn, the effect of noise may be effectively removed by using a moving average filter in an embodiment of the disclosure.

As described above, the controller according to an embodiment of the disclosure may apply a moving average filter as a first filter and additionally apply a second filter to the raw voltage data D1 to Dn. For example, the second filter may be a 1D Kalman filter. The 1D Kalman filter is a type of recursive filter that estimates a state of a linear dynamics system based on current data, and may estimate current data based on a value estimated at an immediately preceding point in time. In this manner, by filtering the raw voltage data D1 to Dn by applying the moving average filter and the 1D Kalman filter together, an increase in delay time due to filtering may be minimized and an average error due to noise may be reduced at the same time.

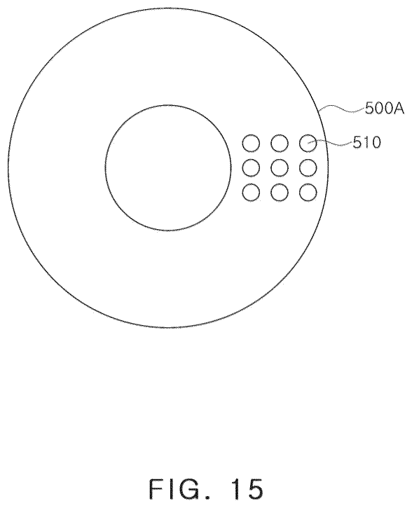

FIGS. 15, 16 and 17 are diagrams illustrating a polishing process apparatus according to an embodiment of the disclosure.

In each of the embodiments illustrated in FIGS. 15 to 17, the polishing process apparatus may include platens 500A, 500B, and 500C and a plurality of eddy current sensors 510, 520, and 530 accommodated in spaces inside the platens 500A, 500B, and 500C. The platens 500A, 500B, and 500C may rotate based on a central driving axis, and at least a portion of a target layer of an object to be polished may be removed by a polishing pad mounted on an upper surface of the platens 500A, 500B, and 500C.

Referring to FIG. 15, the platen 500A may provide a plurality of spaces arranged in a lattice form. Accordingly, as illustrated in FIG. 15, the plurality of eddy current sensors 510 may be arranged in a lattice form in a direction parallel to an upper surface of the platen 500A. When a polishing process is performed, AC power may be applied to each coil of the plurality of eddy current sensors 510 to generate eddy current in the target layer.

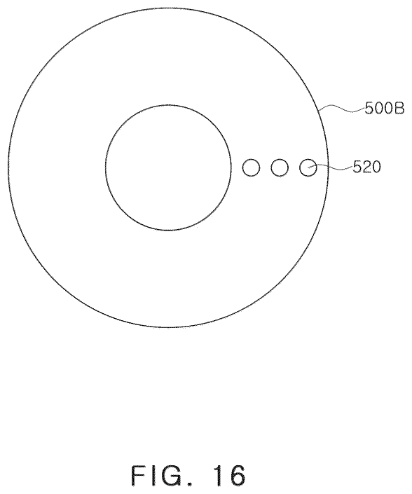

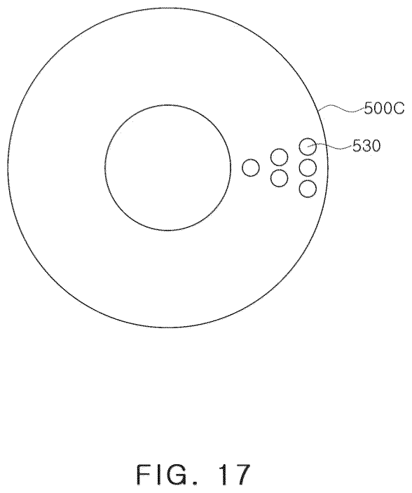

Referring to FIG. 16, the platen 500B may provide a plurality of spaces arranged in a lattice form. Accordingly, as illustrated in FIG. 16, the plurality of eddy current sensors 520 may be arranged in a radial direction extending from the central axis of the platen 500B. In the embodiment illustrated in FIG. 17, a plurality of eddy current sensors 530 may be arranged in a sector shape in a space provided by the platen 500C.

As the platens 500A, 500B, and 500C rotate, the plurality of eddy current sensors 510, 520, and 530 may pass below an object to be polished fixed to a carrier. A controller connected to the plurality of eddy current sensors 510, 520, and 530 may acquire raw voltage data from the plurality of eddy current sensors 510, 520, and 530 at each point in time when the plurality of eddy current sensors 510, 520, and 530 pass below the object. Since the thickness of the target layer decreases as the platens 500A, 500B, and 500C rotate, an intensity of the raw voltage data acquired by the controller from the plurality of eddy current sensors 510, 520, and 530 may change according to the decrease in the thickness of the target layer.

The controller may measure the thickness of the target layer using the raw voltage data obtained from the plurality of eddy current sensors 510, 520, and 530. For example, the controller may configure an image representing the thickness of the target layer by mapping the raw voltage data to the thickness of the target layer, measure the thickness of the target layer based on the image, and determine an end point of the polishing process.

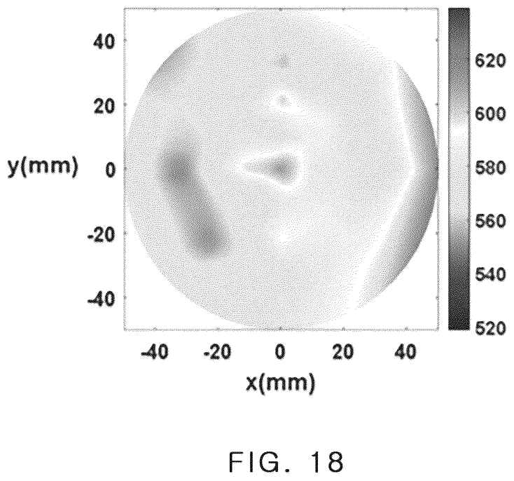

FIG. 18 is a diagram illustrating an operation of a polishing process apparatus according to an embodiment of the disclosure.

FIG. 18 is an image illustrating a thickness of a target layer included in an object to be polished, for example, a wafer. As described above, the controller may configure an image by mapping the raw voltage data acquired from the plurality of eddy current sensors to the thickness of the target layer. Referring to FIG. 18, the controller may determine that the thickness of the target layer has a value ranging from 540 mm to 610 mm depending on the location.

As the polishing process is in progress, the controller may increase the resolution of the plurality of eddy current sensors by increasing a gain of an amplification circuit included in each of the plurality of eddy current sensors. When the resolution of the plurality of eddy current sensors is increased, the effect of reducing the minimum thickness of the target layer that may be measured with the image generated by the controller may be obtained, and as a result, an end point of the polishing process may be accurately determined by tracking the thickness of the target layer more precisely.

According to an embodiment of the disclosure, the eddy current sensor may be disposed within the platen of the polishing process apparatus, and during the polishing process, the thickness of the target layer included in the object may be detected in real time by using eddy current generated by the eddy current sensor. In an embodiment of the disclosure, the thickness of the target layer may be detected, while reducing the minimum thickness that may be detected with the eddy current sensor as the polishing process is in progress, thereby implementing the polishing process apparatus capable of accurately determining an end point of the polishing process by precisely measuring a change in the thickness of the target layer.

Each of the embodiments provided in the above description is not excluded from being associated with one or more features of another example or another embodiment also provided herein or not provided herein but consistent with the disclosure.

While example embodiments have been illustrated and described above, it will be apparent to those skilled in the art that modifications and variations could be made without departing from the scope of the present disclosure as defined by the appended claims.

What is claimed is:

1. A polishing process apparatus comprising:
a carrier configured to support an object;
a platen provided below the carrier and configured to accommodate at least one eddy current sensor, the at least one eddy current sensor comprising:
a coil configured to output an eddy current,
a power supply circuit configured to supply power to the coil, and
a voltage detection circuit connected to the coil and configured to detect raw voltage data,
a polishing pad on an upper surface of the platen, and
a controller configured to:
acquire first data by receiving the raw voltage data from the voltage detection circuit a plurality of times while a polishing process is performed on the object;
acquire second data by sequentially applying a first filter and a second filter to the first data, the first filter being different from the second filter, and
measure a thickness of a target layer included in the object based on the second data.

2. The polishing process apparatus of claim 1, wherein the first filter comprises a moving average filter, and
wherein the second filter comprises a one-dimensional Kalman filter.

3. The polishing process apparatus of claim 1, wherein the voltage detection circuit comprises:
a first resistor configured to receive a coil voltage corresponding to impedance of the coil;
an operational amplifier comprising a first input terminal connected to the first resistor and a second input terminal configured to receive a predetermined reference voltage;
a second resistor connected between the first input terminal and an output terminal of the operational amplifier;
an analog-to-digital converter configured to convert an output voltage of the operational amplifier into the raw voltage data and provide the raw voltage data to the controller; and
a resistance regulator configured to regulate a resistance value of at least one of the first resistor and the second resistor.

4. The polishing process apparatus of claim 3, wherein the controller is further configured to control the resistance regulator to adjust the resistance value based on the raw voltage data decreasing from an initial intensity to a predetermined reference intensity or less.

5. The polishing process apparatus of claim 3, wherein the controller is further configured to control the resistance regulator to regulate the resistance value based on a duration of the polishing process exceeding a predetermined reference time.

6. The polishing process apparatus of claim 1, wherein the voltage detection circuit comprises:
a first resistor configured to receive a coil voltage;
a second resistor connected in series to the first resistor, and
an operational amplifier comprising a first input terminal connected to a node between the first resistor and the second resistor, and
a resistance regulator configured to change a resistance value of the second resistor.

7. The polishing process apparatus of claim 6, wherein the controller is further configured to increase the resistance value of the second resistor based on a duration of the polishing being lapsed.

8. The polishing process apparatus of claim 1, wherein the platen is configured to provide a plurality of spaces separated from each other and arranged in a lattice form, and
wherein the at least one eddy current sensor comprises a plurality of eddy current sensors respectively accommodated in the plurality of spaces.

9. The polishing process apparatus of claim 1, wherein the platen is configured to provide a plurality of spaces arranged in a radial direction, and
wherein the at least one eddy current sensor comprises a plurality of eddy current sensors respectively accommodated in the plurality of spaces.

10. The polishing process apparatus of claim 1, wherein the platen is configured to provide a plurality of spaces arranged in a sector shape, and
wherein the at least one eddy current sensor comprises a plurality of eddy current sensors respectively accommodated in the plurality of spaces.

11. The polishing process apparatus of claim 1, wherein the controller is further configured to an end point of the polishing process by monitoring the thickness of the target layer in real time during the polishing process.

12. A polishing process apparatus comprising:
a carrier configured to support an object;
a platen provided below the carrier and comprising a plurality of spaces configured to accommodate a plurality of eddy current sensors, wherein each of the plurality of eddy current sensors comprises:
a coil,
a power supply circuit configured to supply alternating current (AC) power to the coil, and
a voltage detection circuit configured to detect raw voltage data corresponding to impedance of the coil; and
a polishing pad on an upper surface of the platen and configured to polish a target layer in the object; wherein the voltage detection circuit comprises:
an input resistor configured to receive a coil voltage corresponding to an inductance of the coil,
a feedback resistor connected to the input resistor,
an operational amplifier comprising:
a first input terminal connected to a node between the input resistor and the feedback resistor, and
a second input terminal connected to a reference node; and
a resistance regulator configured to regulate a resistance value of the feedback resistor.

13. The polishing process apparatus of claim 12, wherein the plurality of eddy current sensors are arranged in a lattice form in a first direction and a second direction that are parallel to the upper surface of the platen.

14. The polishing process apparatus of claim 12, wherein the plurality of eddy current sensors are arranged in a radial direction of the platen.

15. The polishing process apparatus of claim 12, wherein the plurality of eddy current sensors are arranged in a sector shape.

16. The polishing process apparatus of claim 12, wherein the resistance regulator is further configured to maintain the resistance value of the feedback resistor at an initial resistance value until an intensity of the raw voltage data decreases to a predetermined reference intensity or less after a polishing process of polishing the target layer starts.

17. The polishing process apparatus of claim 12, wherein the target layer comprises a conductive material.

18. A polishing process apparatus comprising:
a platen configured to provide a space in which at least one eddy current sensor is accommodated, wherein the at least one eddy current sensor comprises:
a coil,
a power supply circuit configured to supply alternating current (AC) power to the coil,
an amplification circuit configured to output an analog voltage signal corresponding to a change in impedance of the coil, and
an analog-to-digital converter (ADC) configured to convert the analog voltage signal into raw voltage data;
a polishing pad on an upper surface of the platen; and
a controller configured to:
acquire raw voltage data from the at least one eddy current sensor;
determine an end point of a polishing process; and
increase a gain of the amplification circuit over time after the polishing process starts.

19. The polishing process apparatus of claim 18, wherein the controller is further configured to generate an image representing a thickness of a target layer contacting the polishing pad by mapping the raw voltage data with the thickness of the target layer during the polishing process.

20. The polishing process apparatus of claim 19, wherein the controller is further configured to acquire first data based on the raw voltage data at each of a plurality of points in time at which the at least one eddy current sensor passes the target layer while the platen rotates.
